(19) United States
(12) Patent Application Publication
(10) Pub. No.: US 2020/0200947 A1
(43) Pub. Date: Jun. 25, 2020

(54) MULTILAYER ANTIREFLECTIVE ARTICLES AND METHODS OF FORMING THE SAME

(71) Applicant: General Plasma, Inc., Tucson, AZ (US)

(72) Inventor: Phong NGO, Tucson, AZ (US)

(21) Appl. No.: 16/640,442

(22) PCT Filed: Aug. 29, 2018
(86) PCT No.: PCT/US2018/048568

§ 371 Date: Feb. 20, 2020

Related U.S. Application Data
(60) Provisional application No. 62/551,317, filed on Aug. 29, 2017.

(51) Int. Cl. G02B 1/118; C23C 16/02; C23C 16/50; C23C 16/40; C23C 28/04; G02B 1/18; G02B 1/14

(52) U.S. Cl. CPC G02B 1/118; C23C 16/0245; C23C 16/50; C23C 16/401; G02B 2207/109; C23C 28/042; G02B 1/18; G02B 1/14; C23C 16/405

(57) ABSTRACT

Multilayer antireflective articles are disclosed. In embodiments, the multilayer antireflective articles include a combination of a moth-eye layer and a multi-layer antireflective stack. The articles can exhibit desirable optical properties for use in various applications, including screen overlays. Methods of forming such articles are also disclosed.

### FIELD

The present disclosure generally relates to multilayer antireflective articles and methods of forming the same. In particular, the present disclosure relates to multilayer antireflective articles that include a combination of a moth-eye layer and a multi-layer antireflective stack, and methods of forming the same.

### BACKGROUND

Electronic devices such as computer monitors, smart phones, tablet computers, laptops, etc. include a display for conveying information to a user. These displays have a cover layer (e.g., of glass or another material) integral to the display for protection of underlying device components, and to provide an interface (e.g., touch screen) through which a user may interact. Such cover layers can reflect an undesirable amount of incident light when the device is used outdoors or in another highly illuminated environment. Uncoated glass, for example, has refractive index of 1.52 and can reflect more than 4.5% of incident light (photopic reflectance in the visible spectrum ranging from 400 nanometers (nm) to 700 nm). That reflectance can make it challenging for a user of a device with an uncoated glass cover layer to view content on the device in high ambient lighting conditions. The high photopic reflectance of uncoated glass can also undesirably reduce the color contrast of the display.

An antireflective (AR) coating directly on the cover layer of a mobile display can effectively address the above noted problems, but is rarely used in such applications. This is due to previously unsolved challenges related to durability, environmental stability and optical performance specifications. For example, smart phones are frequently stowed in pockets or purses where the display cover layer is rubbed and scratched by keys and other objects. They are also often utilized in hot and humid environments. Such devices are also frequently handled, resulting in the deposition of oils and personal cosmetic products on the display. Consequently, AR coatings for mobile devices may need to meet challenging product specifications. Moreover, any AR coating for a mobile device application must be amenable to high volume, high yield mass production.

An alternative to depositing an AR coating directly on an integral cover layer of a display is to apply an antireflective overlay to the integral cover layer, e.g., as a “screen protector.” Such screen protectors, are often after-market products applied by a consumer to the cover layer using an adhesive that is optically matched to eliminate reflections on the cover layer, so that a higher reflectance surface becomes the air contacting surface of the overlay. For instance, an overlay made of polyethylene terephthalate may reflect 4.4% of ambient light in high ambient light conditions. With the foregoing in mind, an AR coating for such an overlay will be subject to the same environmental stresses as an AR coated cover layer, and thus needs to meet the same challenging durability, environmental and optical performance requirements as above. Meeting these requirements may be challenging, particularly when an overlay including a plastic substrate is used. This is because plastic is generally softer material than glass (the substrate for an AR coated cover layer), and because the hygroscopic nature of plastic can hinder the adhesion of an AR coating thereto.

In an earlier patent application by the present inventor (PCT/US18/33883), an improved AR coated article is disclosed that comprises a substrate with a hard-coat layer with a moth eye layer etched into the hard-coat layer, an adhesion layer is deposited on the moth eye layer and an AR stack is deposited on the adhesion layer. This improved AR coated article largely solves the problems associated with mobile AR coated devices, particularly for those with plastic cover layers or plastic overlays. After the PCT/US18/33883 application, the present inventor discovered a coating structure that, among other benefits, further improved the anti-scratch durability of the AR coated article. That and other improvements are the subject of this present disclosure.

### BRIEF DESCRIPTION OF THE DRAWINGS

FIG. 1A is a cross-sectional diagram schematically illustrating a layer structure of one example of a multi-layer antireflective article consistent with the present disclosure;

FIG. 1B is a cross-sectional diagram showing detail of one example of a multilayer antireflective stack consistent with the present disclosure.

FIG. 2 is a schematic drawing of one example of an ion beam plasma etch process that may be used to create a moth eye layer consistent with the present disclosure;

FIG. 3 is comparison plot of light reflectance (in percent) versus wavelength (in nanometers) between an actual measurement of a base structure 101 (i.e., before the formation of a moth eye layer), an actual measurement of a layer stack after formation of a moth eye layer 111, and simulation results of an optical model of a structure with moth eye layer 111 on top of a base structure 101.

FIG. 4 is another magnified cross-sectional diagram schematically illustrating an example layer structure of an adhesion layer 113 on top of moth eye layer 111 consistent with the present disclosure.

FIG. 5 is comparison plot of light reflectance (in percent) versus wavelength (in nanometers) between an actual measurement of a layer stack consistent with the structure of FIG. 4 (501), simulation results of an optical model of the structure of FIG. 4 in which the moth eye layer and adhesion layer are treated as independent discreet optical layers (503), simulation results of an optical model of FIG. 4 in which the adhesion layer is modeled as partially filling voids of a moth eye layer and the adhesion layer (505), and simulation results of an optical model of the structure of FIG. 4 in which the optical effect of the moth eye layer is ignored (507).

FIG. 6A is an SEM image depicting partial formation of a moth eye layer 111 on a hard coat layer, consistent with the present disclosure;

FIG. 6B is a magnified SEM image depicting the surface topology of a moth eye layer consistent with the present disclosure;

FIG. 7A is an SEM image depicting the surface topology of a layer stack after an adhesion layer 113 is deposited on top of moth eye layer 101, consistent with the present disclosure

FIG. 7B is an SEM image of a cross section of the layer stack of in FIG. 7A, showing an interface between a moth eye layer 111 and an adhesion layer 113 of an AR stack, consistent with the present disclosure.

FIG. 7C depicts a magnified region of the SEM image of FIG. 7B, showing further details of an interface between a moth eye layer 111 and an adhesion layer 113 of an AR stack, consistent with the present disclosure.

FIG. 8 is cross-sectional diagram of one example of a multi-layer anti-reflective article consistent with the present disclosure.

FIG. 9A is a cross-sectional diagram of one example of a multi-layer anti-reflective article that includes an anti-smudge layer on top of an AR stack, consistent with the present disclosure.

FIG. 9B is a cross sectional diagram showing further detail of one example of an anti-smudge layer consistent with the present disclosure.

FIG. 10 is comparison plot of light reflectance (in percent) versus wavelength (in nanometers) between an actual measurement of a multilayer antireflective article consistent the structure of FIG. 8, simulation results of an optical model of the structure of FIG. 8, in which the multi-layer antireflective stack, adhesion layer, and moth eye layer are treated as discreet optical layers, and simulation results of an optical model of the structure of FIG. 8, in which the moth eye layer is ignored.

FIG. 11 is an SEM image depicting the surface topology of a multilayer antireflective article consistent with the structure of FIG. 8.

FIG. 12 is a plot of light reflectance (in percent) versus wavelength (in nanometers) of one example of a multilayer antireflective article consistent with the structure of FIG. 9A, in which the thickness of the uppermost (top) layer of an antireflective stack is tailored to account for the optical effect of an overlying anti-smudge layer.

### DETAILED DESCRIPTION

The present disclosure generally relates to multilayer antireflective (AR) articles and methods for making the same. Such articles may exhibit a desirable combination of low visible light reflectance, high durability, and strong adhesion, making them well suited for mobile devices and other applications. In particular, the multilayer AR articles described herein are suitable for use as an AR overlay for the display cover layer of a mobile device or an automotive information display.

In developing the technologies described herein, continued progress in combining a moth eye layer with deposited AR layers resulted in the development of an accurate optical model for the moth eye layer. In previously filed international application no PCT/US18/33883, a moth eye layer was optically measured to determine the effective refractive index. Subsequently a non-conformal adhesion layer was deposited and the total reflection of the intermediate article, the base substrate, moth eye and adhesion layer were optically measured. The intermediate article reflectance measurement was then used as the ‘substrate’ to design an AR stack deposited on the conformal adhesion layer. In contrast, in the present disclosure the moth eye layer is modeled as a single optical layer. This allows the optical reflectance of the entire article structure, the substrate with hard coat, moth eye structure, and all deposited layers to be modeled, including reflectance of individual layers and the total article.

In embodiments the multilayer AR articles described herein include a base structure, a moth eye layer, an adhesion layer and an AR stack. The base structure includes a substrate and a hard-coat layer on an upper surface of the substrate. The moth eye layer is etched into and is integral with an upper surface of the hard coat layer. A series of thin film layers are deposited sequentially on the moth eye layer. The series of thin film layers include an adhesion layer deposited on the moth eye layer, and an AR stack deposited on the adhesion layer. The AR stack includes a plurality of layers of differing refractive index. An optional anti-smudge layer may be disposed on the uppermost layer of the AR stack. The base structure may also include an optional adhesive layer and optional release liner, to facilitate application of the multilayer AR article to the cover layer of a display. Mobile devices including a display and a multilayer AR article (consistent with the present disclosure) applied to the cover layer are also described.

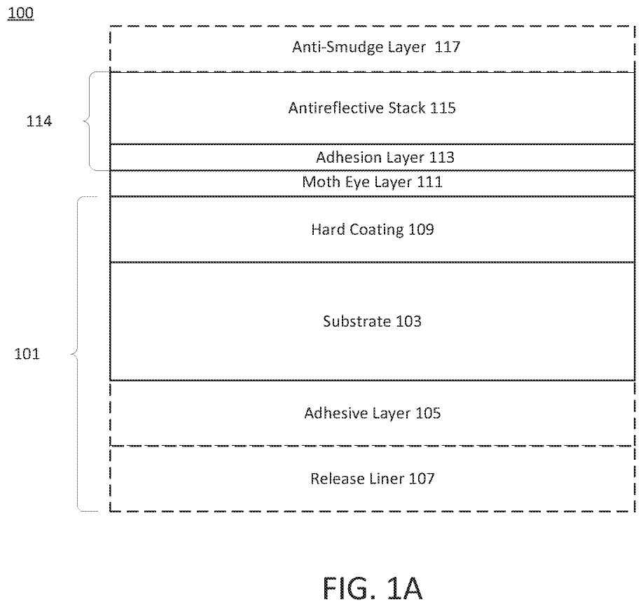

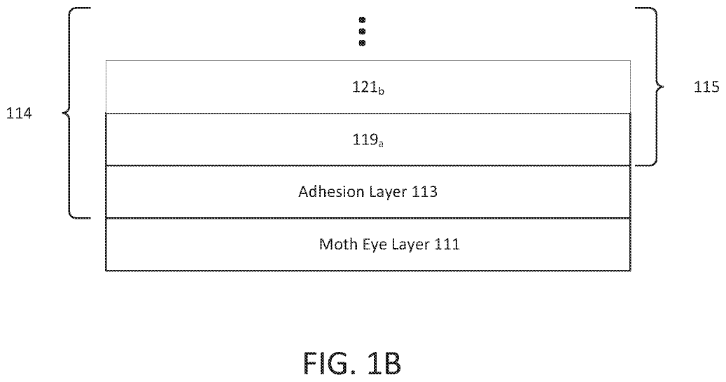

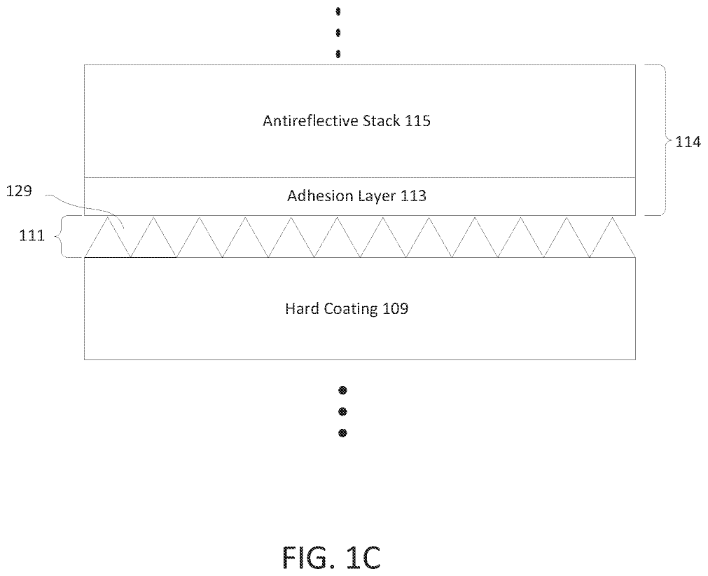

FIG. 1A is a cross sectional diagram that schematically illustrates a layer structure of one example of a multi-layer antireflective (AR) article 100 consistent with the present disclosure. In embodiments, the multilayer AR article 100 includes a base structure 101, a moth eye layer 111, deposited layers 114 and an optional anti-smudge layer 117. Deposited layers 114 include adhesion layer 113 and AR stack 115. AR stack 115 is in the form of a plurality of alternating layers of differing refractive indices. For example, and as shown in FIG. 1B, AR stack 115 may include alternating layers of low (119a) and high (121b) refractive index. For convenience, the layers of low refractive index may be referred to as low refractive index layers, and the layers of high refractive index may be referred to herein as high refractive index layers. In embodiments, adhesion layer 113 is a non-conformally deposited layer on moth eye layer 111 and provides an adherent interface between moth eye layer 111 and AR stack 115. As used herein, the term “non-conformal” when used in reference to an adhesion layer, means that the adhesion layer fills less than 30% of a total volume of voids in a layer on which the adhesion layer is directly formed, e.g., a moth eye layer. In embodiments, the non-conformal adhesion layers fill less than 30%, less than 20% or even less than 10% of the total volume of voids in a layer on which the adhesion layer is directly formed (e.g., a moth eye layer).

The base structure 101 includes a substrate 103 and a hard coating 109 on (e.g., directly on) an upper surface thereof. The substrate 103 may be flexible or rigid, and may be formed from any suitable material. Non-limiting examples of suitable materials that may be used as substrate 103 include flexible plastics, rigid plastics, and glass. In embodiments the substrate 103 is or includes a polymer such as an acrylic or a terephthalate polymer (PET). Without limitation, in some embodiments the substrate 103 is a polyethylene terephthalate (PET) film with a refractive index of about 1.6 (e.g., about 1.64) at 632 nanometers (nm).

The thickness of the substrate 103 may vary widely. For example, the thickness of substrate 103 may range from 12 microns (μm) (for a relatively thin plastic film) to greater than 1 centimeter (cm) (e.g., for relatively thick acrylic sheet). In some embodiments substrate 103 is a polymer film, wherein the thickness of the polymer film ranges from greater than 0 to about 500 (μm). For example, substrate 103 may be a PET film having a thickness of about 50 to about 150 μm, such as about 100 μm. In other embodiments the substrate 103 is a polymer sheet (e.g., an acrylic sheet) having a thickness greater than or equal to about 5 millimeters (mm).

In embodiments the base structure 101 includes a hard coating 109 formed on (e.g., directly on) an upper surface of the substrate 103. One purpose of the hard coating 109 is to improve the scratch and abrasion resistance of the substrate 103. A wide variety of hard coatings are known, and any suitable hard coating composition may be used as hard coating 109. Non-limiting examples of suitable materials that may be used as hard coating 109 include alkoxides, silicon oxides, and silicon oxynitrides. In embodiments hard coating 109 is an alkoxide hard coating formed from a precursor of a metal alkoxide (e.g., a silicon alkoxide precursor). In other embodiments hard coating 109 is formed from or includes SiOₓ, where x ranges from greater than 0 to 2. In still further embodiments hard coating 109 is or includes a SiO₂ polymeric composite hard coating. And in yet further embodiments, hard coating 109 is a silicon oxynitride hard coating (e.g., SiOₓN_{y}). Without limitation, in some embodiments the hard coating 109 is formed from or includes a silicon and oxygen containing hard coating, such as but not limited to a silicon alkoxide hard coating and/or a silicon oxide polymeric hard coating. Such hard coatings may be applied or formed in any suitable manner, such as by a wet-coating and thermal or UV curing process.

The thickness of the hard coating 109 may vary widely, and hard coatings of any suitable thickness may be used. In embodiments the hard coating 109 has a thickness ranging from greater than 200 nm to about 20 μm or more. Without limitation, in some embodiments the hard coating 109 is a silicon and oxygen containing hard coating having a thickness of greater than 1 micron to about 5 microns, such as about 5 microns. In embodiments the refractive index of the hard coating is about 1.5 (e.g., about 1.56) at 632 nm, though any suitable refractive index may be used.

The hardness of the base structure may vary widely, and base structures with any suitable hardness may be used. In embodiments the base structure includes at least a substrate 103 and a hard coating 109 (e.g., a silicon and oxygen containing hard coating), and exhibits a pencil hardness ranging from about 1H to 5H, such as about 3H.

The base structure 101 may further include an optional adhesive layer 105. When used, the adhesive layer 105 may function to enhance the coupling/adherence of the multilayer AR article 100 to the surface of a display. The adhesive layer 105 may also be configured to serve as an index matching layer between the substrate 103 and a cover layer/surface of a display on which the multilayer AR article 100 is installed. In such instances adhesive layer 105 may function to reduce internal reflectance due to differences in the optical index of those components.

A wide variety of adhesives may be used as or in the optional adhesive layer 105. Non-limiting examples of such adhesives include high and low tack adhesives, which may be formed from or include one or more silicone adhesives, acrylic adhesives, synthetic block copolymer adhesives, combinations thereof, and the like. In some embodiments, the optional adhesive layer 105 is formed from or includes a repositionable adhesive, such as but not limited to a repositionable adhesive that may permit multilayer AR article 100 to be removed from the surface of a display of a mobile or other electronic device without leaving an adhesive residue. Without limitation, in some embodiments the optional adhesive layer 105 is a silicone adhesive that is configured to provide a bubble free, low tack, easily wettable attachment to a display of a mobile device. An optional release liner 107 may be also be used, e.g., to facilitate handling of a multilayer AR article 100 that includes an optional adhesive layer 105, and to protect the adhesively layer 105 prior to the installation of multilayer AR article 100 on a display.

The multilayer AR article 100 further includes a moth eye layer 111 that is formed on or integral with an upper surface of hard coating 109. Without limitation, in embodiments the moth eye layer 111 is formed by etching an upper surface of the hard coating 109 to form moth eye structures. In such instances the moth eye layer 111 is not a “layer” that is discrete from the hard coating 109, but rather is a region of the hard coating 109 that has been etched or otherwise processed to include moth eye structures. In general, and as would be understood by those of skill in the art, the moth eye layer 111 is configured to produce an optical effect that can reduce incident light reflection from a surface. Moth eye structures are small, repeated features that are like the natural anti-reflective structures found in the eye of a moth and include arrays of protuberances and cavities having individual feature dimensions of less than half wavelength (λ/2) or the diffraction limit of incident light. As the wave of incident light passing through air encounters moth eye structures, part of the light encounters the material forming the structure (i.e., hits a protuberance) and part continues in air (i.e., within a cavity). The resulting graded or transitional encounter with the moth eye layer material creates an intermediate effective refractive index ‘layer’ that is between the refractive index of air and of the material forming the protuberances, thereby reducing the amount of incident light that is reflected from the moth eye layer.

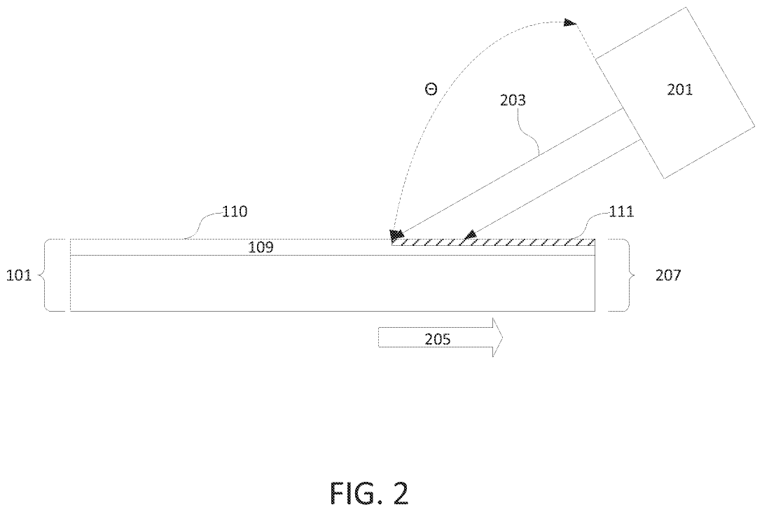

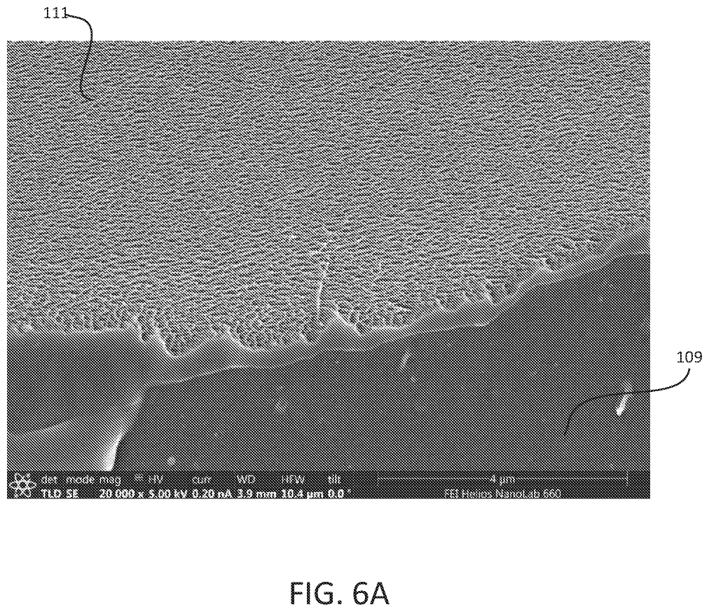

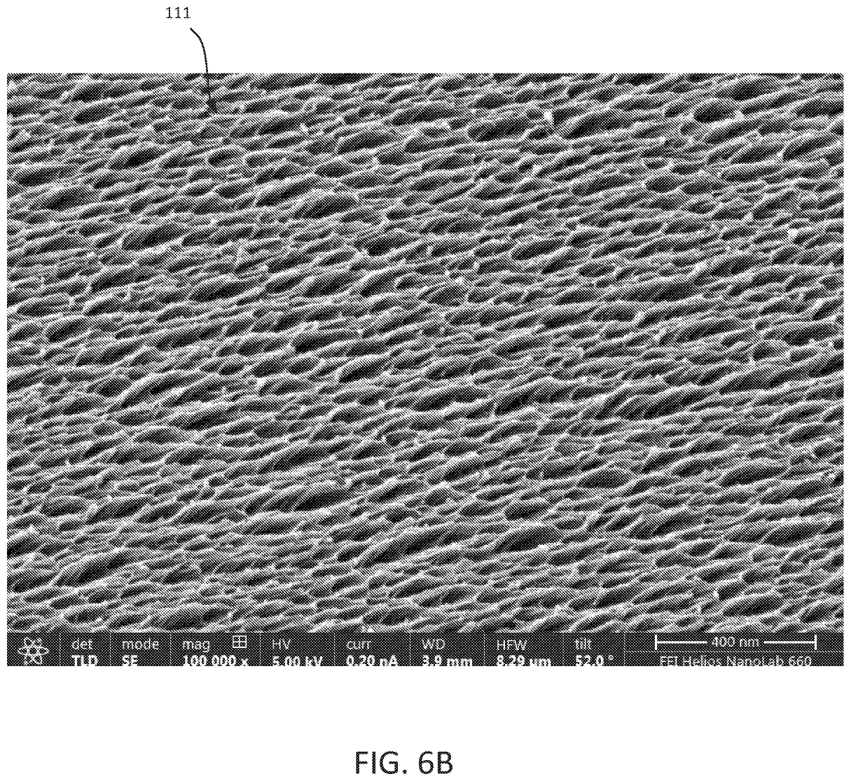

In embodiments the moth eye layer 111 is formed by subjecting the upper surface of the hard coating 109 to a plasma etch process. The plasma etch process may etch or otherwise remove portions of the hard coating 109, resulting in the formation of moth eye structures therein/thereon and, consequently, the formation of moth eye layer 111. To illustrate this concept reference is made to FIG. 2 and FIGS. 6A-6B. FIG. 2 is a schematic depicting the conversion of a portion of hard coating 109 into a moth eye layer 111 using a plasma etch apparatus 201. In the illustrated embodiment the plasma etch apparatus 201 includes a linear ion source that is configured to generate an ion beam 203 that is used to plasma etch hard coating 109. Example linear ion sources that may be used include anode layer type linear ion sources, such as but not limited to the GENERAL PLASMA™ PPALS30 anode layer ion source.

More specifically, to form moth eye layer 111 a base structure 101 may be placed in a vacuum chamber (not shown). The vacuum chamber may contain the plasma etch apparatus 201. The ion source of the plasma etch apparatus 201 may be operable to emit an ion beam 203 towards base structure 101 or, more specifically, towards an upper surface of the hard coating 109. In embodiments, the ion beam 203 is or includes oxygen ions, though other ions may also be used depending on the composition of the hard coating 109. As the base structure 101 is moved relative to the plasma etch apparatus 201 (e.g., in direction 205), the ion beam 203 mechanically sputters off and/or chemically etches at least a portion of the hard coating 109 in a region proximate the upper surface thereof, resulting in the formation of moth eye layer 111. In embodiments the hard coating 109 is or includes a silicon and oxygen containing polymeric hard coating, and the ion beam 203 is configured to remove polymeric carbon and hydrogen components from the hard coating 109, thereby producing a moth eye layer 111 in the form of an exposed network of protuberances and voids.

The angle at which ions in the ion beam 203 are incident on the surface of the hard coating 109 (i.e., the incidence angle of ion beam 203) may impact the structural features of the resultant moth eye layer 111 and, thus, the adhesion of layers that are subsequently formed on the moth eye layer 111. It may therefore be desirable to control the incidence angle Θ of the ion beam 203 on the upper surface of the hard coating 109 such that the ions in ion beam 203 are incident on the upper surface of the hard coating 109 within a desired incidence angle range, or even at a specific incidence angle. In embodiments, the incidence angle Θ of the ion beam 203 on the surface of the hard coating 109 ranges from greater than 0 to about 90 degrees, such as from about 10 to about 70 degrees, about 20 to about 50 degrees, or even about 30 to about 45 degrees. Without limitation, in some embodiments the incidence angle Θ of the ion beam 203 is about 45 degrees.

FIG. 6A is a scanning electron microscope (SEM) image depicting a moth eye layer 111 (or, more particularly, moth eye structures) formed on a portion of a hard coating 109. The lower right side of the figure shows the untreated surface of a polymeric hard coating 109 formed on a PET substrate (not shown). The upper left side of the figure shows moth eye structures of the moth eye layer 111 that are formed by plasma etch, i.e., by exposing the hard coating 109 to an ion beam consisting of oxygen ions that were incident on the surface of the hard coating 109 at an incidence angle of 45 degrees. The oxygen ions were generated by operating an ion source of a plasma etch apparatus at a voltage of 2500V with an ion source power supply discharge current of 400 milli-amperes (mA) using oxygen gas. The substrate was moved past the ion source at a rate of 0.5 meters (m) per minute. The pressure in the vacuum chamber was less than 1 mTorr.

Further detail of the surface of the moth eye layer 111 can be seen in FIG. 6B, which is an SEM image of a portion of the moth eye layer 111 of FIG. 6A at higher magnification. Formation of the moth eye layer 111 may be completed by moving the base structure 101 relative to the ion source, moving the ion source relative to the base structure, or both. FIGS. 6A and 6B demonstrate that the plasma etch process significantly alters the upper surface of the hard coating layer 109, resulting in the formation of the moth eye layer 111. Multiple benefits are gained by forming of moth eye layer 111 including providing a low effective refractive index layer and improving the adhesion of subsequently deposited layers.

The moth eye structures in moth eye layer 111 can be modeled as an individual optical element consisting of a material having two refractive indices, I1 and I2, where I1 is the refractive index of the material forming the moth eye structures, I2 is the refractive index of voids (e.g., air or vacuum) 129 at an interface between the moth eye layer 111 and adhesion layer 113. From this viewpoint an effective refractive index of the moth eye layer 111 can be calculated as a relative combination of I1 and I2. For example, in a preferred embodiment the hard coating 109 is processed to form a moth eye layer 111. The moth eye layer 111 is configured such that it includes protuberances and valleys, wherein the valleys are formed to a depth of about 60 nm. An effective refractive index (ERI) of the moth eye layer 111 may be defined by a combination of a first refractive index, I1, and a second refractive index, I2, wherein the combination is weighted by the “packing density” (PD) of the moth eye layer 111. More specifically, ERI=I1+I2, where I1=n1*PD and I2=n2*(1−PD), in which n1 is the refractive index of the material forming the moth eye structures of the moth eye layer 111 (e.g., the refractive index of hard coating 109), and n2 is the refractive index of the material of the voids (e.g., air or vacuum). The “packing density” of the moth eye layer is the amount (in percent) of the moth eye layer 111 that is formed by the material of hard coating 109. For example, hard coating 109 may be formed from a material having a refractive index of 1.56. A moth eye layer 111 may be formed by processing the hard coating 109 as discussed above, such that the moth eye layer has a packing density of 64%. The effective refractive index (ERI) of the moth eye layer 111 may be calculated as follows: ERI=(1.56*0.64)+(1*0.36)=1.36.

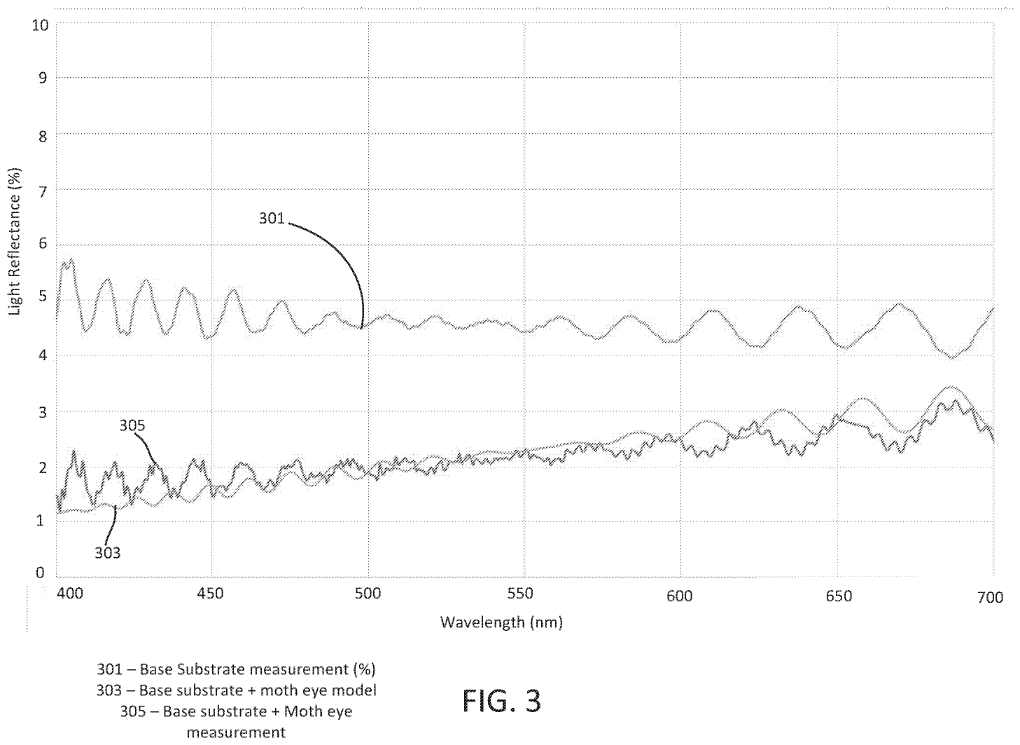

Using the above method and once the packing density of a moth eye layer is known, the moth eye layer can be modeled as an individual optical element in a multilayer optical stack or article. That concept is demonstrated in FIG. 3, in which plot 305 is an actual measurement of a stack 207 (FIG. 2) including a moth eye layer 111 of the reflectance in the visible range (about 375-725 nm), and Plot 303 is the modeled reflectance for the moth eye layer 111. As shown, the modeled reflectance plot 303 of stack 207, where moth eye layer 111 is modeled as an individual optical element, closely approximates the actual measurement 305. FIG. 3 also shows a plot 301 of base structure 101 without moth eye layer 111. As shown, when moth eye layer 111 is etched into hard coat 109 to form structure 207, the measured reflectance of the resulting structure is reduced by about 55-60%, relative to the reflectance of base structure 101.

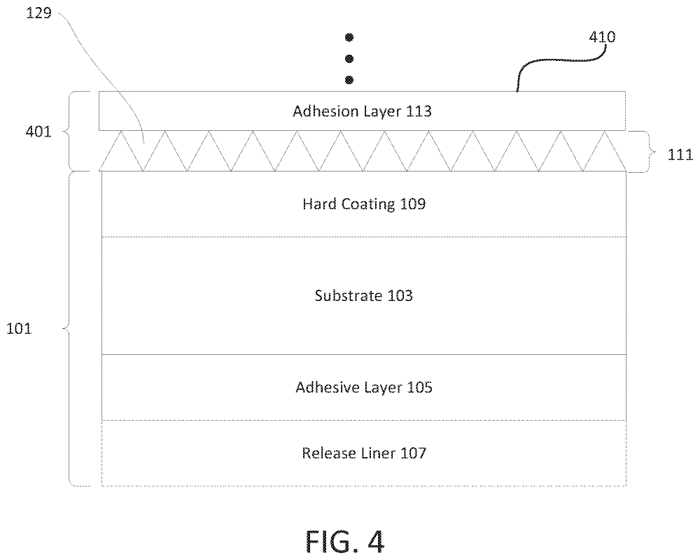

Returning to FIG. 1A, AR article 100 further includes an adhesion layer 113 on the moth eye layer 111. In embodiments, the adhesion layer 113 is deposited on and bonds to moth eye layer 111 without significantly filling the voids 129 of moth eye layer 111 as schematically depicted in FIG. 4. Put differently, adhesion layer 113 is in the form of a non-conformal layer that is on (e.g., directly on) moth eye layer 111. Even though the adhesion layer 113 is a non-conformal layer, adequate interlayer adhesion between it and the moth eye layer 111 can be attained, as evidenced by the examples discussed later.

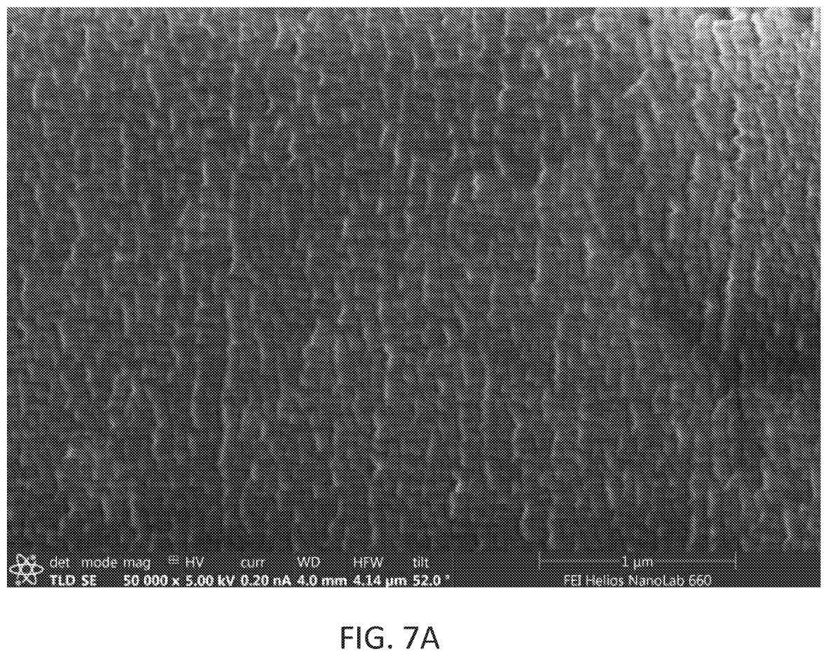

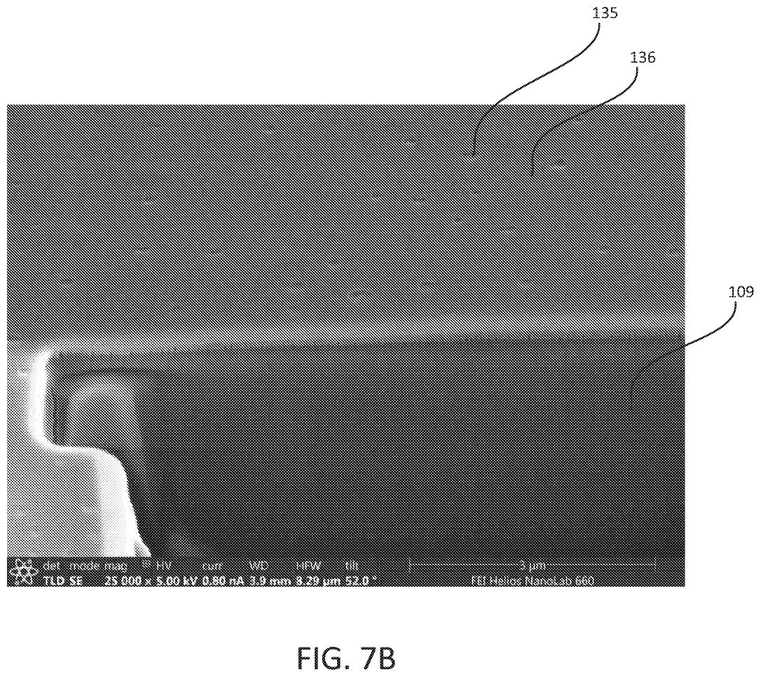

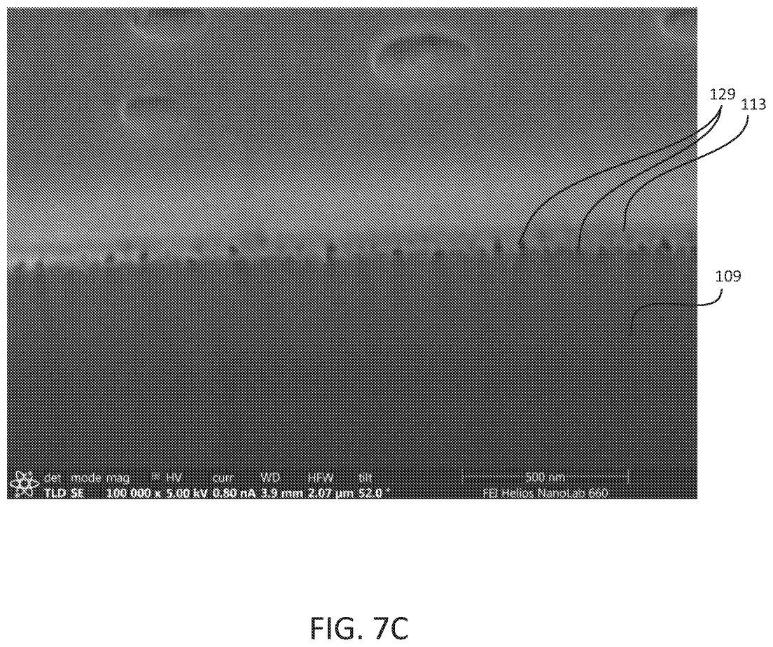

FIG. 7A is an SEM image of the surface 410 of a SiO2 adhesion layer 113 deposited on a moth eye layer 111 in a structure similar to FIG. 4. As can be seen in the image, the adhesion layer 113 largely covers the surface roughness of the moth eye layer 111. FIGS. 7B and 7C are SEM images of a cross section of the structure shown in FIG. 4. As shown, the structure includes an adhesion layer 113 deposited on top of moth eye layer 111. As can be seen, particularly in FIG. 7C, voids 129 of the moth eye layer 111 remain unfilled after the deposition of adhesion layer 113. Thus, adhesion layer 113 is a non-conformal layer on moth eye layer 111. It is noted that that depiction of upper surface 136 and spots 135 appearing on the top surface in the SEM images in FIGS. 7B and 7C are from a permanent marker. This is a common technique used in SEM imaging to achieve sharp cross-section images after the ion-milling step and therefore not a representation of adhesion layer 113 surface.

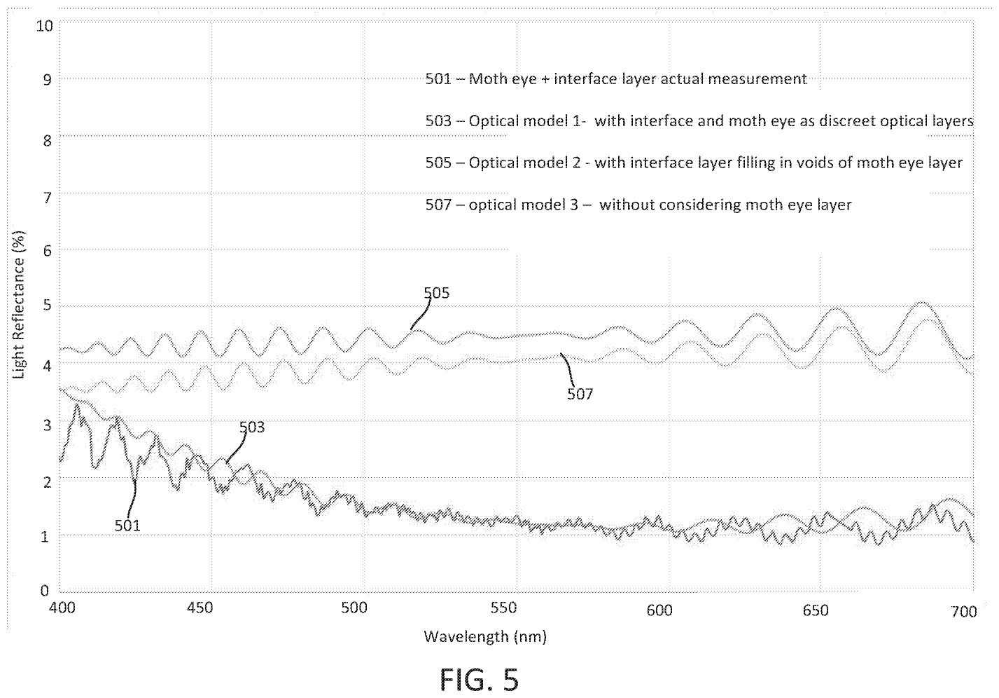

FIG. 5 shows comparison plots of light reflectance (in percent) versus wavelength (in nanometers), and further demonstrates that voids 129 are not filled by adhesion layer 113 and thus, adhesion layer 113 is a nonconformal layer. In FIG. 5, plot 501 is an actual measurement of a layer stack including a deposited adhesion layer 113 on a moth eye layer 111 with base substrate 101 consistent with FIG. 4. Plot 503 is a model of the Plot 501 structure that considers the adhesion layer 113, moth eye layer 111 and base structure 101 as individual optical elements. In plot 503, the moth eye layer 111 voids 129 are modeled as containing air or vacuum. Adhesion layer 113 is modeled as a SiOx layer 37 nm thick. As shown, plot 503 agrees closely with actual measurement depicted by plot 501, thereby demonstrating that the moth eye voids 129 are not filled (or not significantly filled) by adhesion layer 113. If voids 129 were filled by adhesion layer 113, the moth eye anti-reflection performance would decrease and the actual measurement plot 501 would not closely correlate to model plot 503.

Returning to FIG. 5, plot 505 models the reflectance performance condition where adhesion layer 113 does fill the moth eye layer 111 voids 129. Plot 507 is an optical model of the FIG. 4 structure without moth eye layer 111. As can be seen, the actual measurement of the FIG. 4 article including the moth eye layer and adhesion layer 113 correlates closely to a model where the moth eye layer 111 remain relatively unaltered after deposition of adhesion layer 113. In embodiments therefore, the AR articles described herein include an optical layer (i.e., adhesion layer 113) on a moth eye layer 111 wherein voids 129 within the moth eye layer 111 remain filled with air or vacuum (instead of being filled by adhesion layer 113) such that the refractive index and optical reflection benefits of the moth eye layer are largely retained.

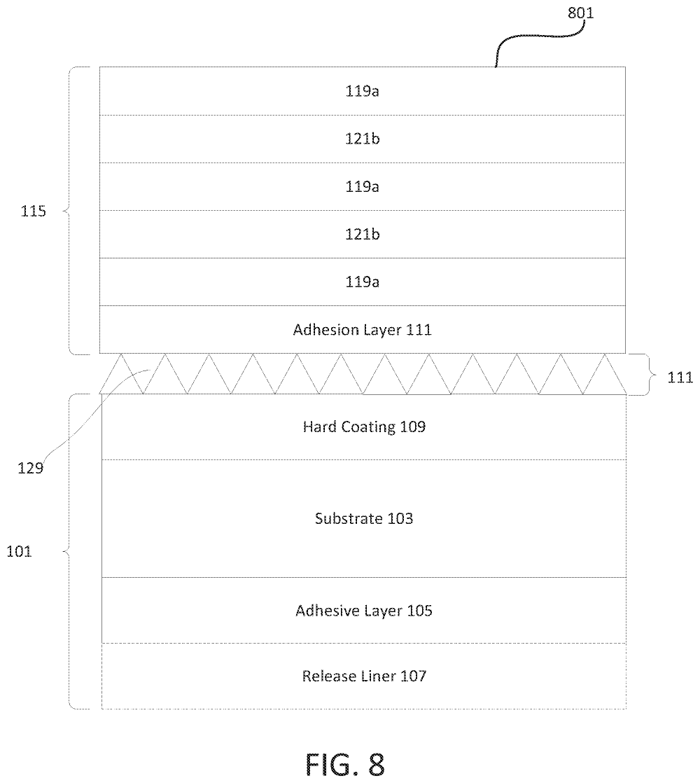

Use of a combined moth eye layer 111 and adhesion layer 113 can also improve the adhesion of subsequent layers applied after adhesion layer 113. To demonstrate that improvement tests were conducted to compare the adhesion performance of first articles to the adhesion performance of second articles. The first articles included a moth eye layer 111 on a base structure 101, an adhesion layer 113 on the moth eye layer 111, and an AR stack 115 on the adhesion layer, as shown in FIG. 8. The second articles were identical to the first articles, except that they did not include the moth eye layer 111. The adhesion of the deposited layers 114 of the first and second articles was evaluated using a grid-and-tape test method (ASTM D3359-09) after the articles were exposed to environmental chamber set at 60-degree C. and 90% humidity for measured time lengths. The first articles including the moth eye layer 111 passed the grid-and-tape test with 5B performance (no visible loss of adhesion) for over 30 days of heat/humidity exposure. In contrast, the second articles (i.e., those lacking moth eye layer 111), failed the grid-and-tape test after 24 hours of heat/humidity exposure.

The adhesion layer 113 may be formed from any suitable material, and the choice of material used may be based upon the optical properties of the material and the ability to form an adherent layer on moth eye layer 111 without significantly filling voids 129 (i.e., a non-conformal layer). Non-limiting examples of suitable materials that may be used to form adhesion layer 113 include SiOₓ compositions, such as but not limited to silicon oxide and silicon dioxide.

The adhesion layers described herein may be formed in any suitable manner. For example, adhesion layer 113 may be formed by plasma enhanced chemical vapor deposition (PE-CVD). Such deposition may be accomplished in a vacuum or other chamber using any suitable PE-CVD apparatus, such as but not limited to a PE-CVD apparatus that utilizes the alternating current (AC) ion source described in U.S. Pat. No. 9,136,086. Such an AC ion source can be used to deposit metal oxide films like SiOₓ and TiOₓ via PE-CVD at high rates and with good density, uniformity and stability. In some embodiments the adhesion layer 113 is a SiOₓ layer formed by PE-CVD using HMDSO (hexamethyldisiloxane) as a precursor vapor and oxygen and argon gases. Of course, such precursor vapor is enumerated for the sake of example, and other precursor vapors may be used. In any case, following formation of the adhesion layer 113 an intermediate product including a layer stack 401 is formed, as shown in FIG. 4. In embodiments, adhesion layer 113 may be deposited at a reduced power and a more precursor rich process relative to other optical layers. This may facilitate the production of a non-conformal adhesion layer 113. One such process is enumerated in the examples described later.

The thickness of adhesion layer described herein may vary widely and adhesion layers of any suitable thickness may be used. In embodiments the thickness of the adhesion layer 113 ranges from greater than 0 to 10 microns or more, such as from greater than 0 to about 100 nm. In one non-limiting embodiment the adhesion layer 113 is formed of SiOx, and has a thickness of about 37 nm.

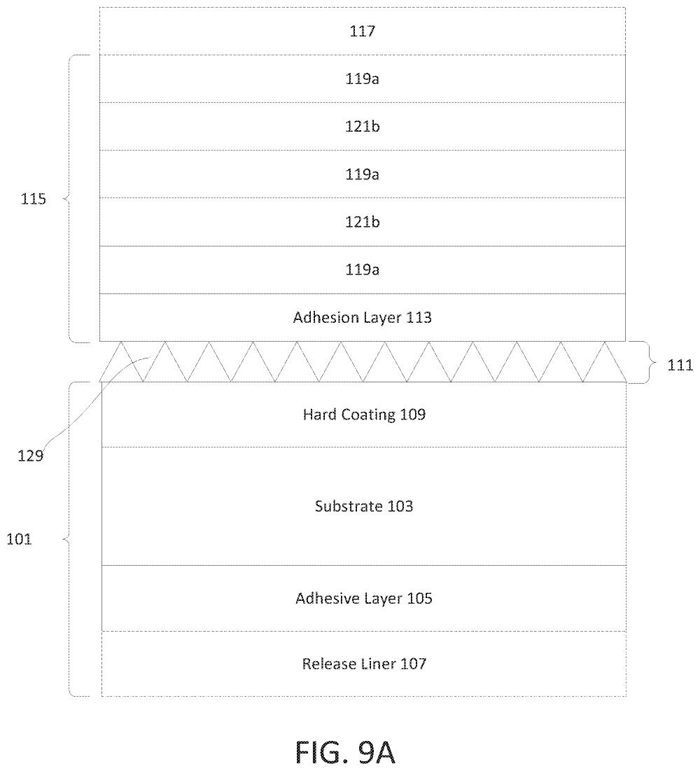

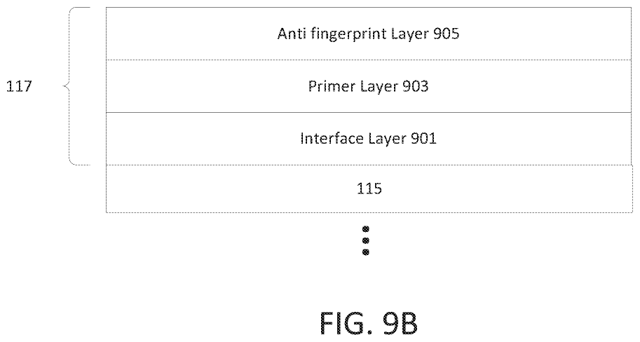

Following the formation of the adhesion layer 113 and as shown in FIGS. 1 and 8, a plurality of alternating layers of differing refractive index may be formed on adhesion layer 113, resulting in the formation of AR stack 115. Subsequently and as shown in FIGS. 9A and 9B, an optional anti-smudge layer 117 may be formed on the AR stack 115.

In the embodiment of FIG. 8, the AR stack 115 includes a plurality of first layers 119a and second layers 121b, wherein the first and second layers differ in refractive index and a and b are integers. In general, the refractive indices of the first and second layers 119a and 121b may range from greater than 1 to about 4.

Several of the figures depict embodiments of a multilayer AR article 100 in which AR stack 115 includes a total of five alternating first and second layers 119a, 121b, which are formed over an adhesion layer 113. Such illustration is for the sake of example only, and any suitable number of first and second layers 119a, 121b may be used. For example, the number of first and second layers 119a, 121b may range from greater than or equal to 1, such as but not limited to 2, 3, 4, 5, 6, 7, 8, 9, 10 or more. The total number of first and second layers 119a, 121b in AR stack 115 may, therefore, be greater than or equal to 2, such as 4, 6, 8, 10, 12, 14, 16, 18, 20, or more. In general, AR stack 115 is configured to provide an antireflection effect to multilayer AR article 100 in which the moth eye layer 111 and adhesion layer 113 are part of the overall optical performance.

The composition of the first and second layers 119a, 121b may vary widely, and any suitable material may be used to form such layers. Without limitation, in some embodiments the first and second layers 119a, 121b are each formed from a metal (e.g., Ti, Si, Zr, Mg, Ta etc.), a metal oxide (e.g., SiO, SiO2, TiO₂, ZrO, MgO, TaO, Ta₂O₅ etc.), a metal nitride (e.g., SiN, TiN, ZrN, TaN, etc.)), combinations thereof and the like. Without limitation, in some embodiments the layers 119a are each formed from SiO2, and the layers 121 are formed from TiO₂.

While the present disclosure focuses on embodiments in which AR stack 115 includes two different types of layers (i.e., first layers 119a and second layers 121b), the instant application is not limited to such configurations. Indeed, the present disclosure envisions embodiments in which AR stack 115 includes more than two (e.g., 3, 4, 5 etc.) different types of layers therein, wherein each type of such layers differs in composition from each other type of layer in the AR stack 115.

The layers of AR stack 115 may be formed in any suitable manner. For example, the layers 119a, 121b may be formed using a PE-CVD process, such as the PE CVD process described above regarding the formation of adhesion layer 113. Of course, the layers 119a, 121b may be made by other processes, such as but not limited to physical vapor deposition (e.g., thermal evaporation, sputtering, magnetron sputtering, etc.), atomic layer deposition, wet deposition methods, combinations thereof, and the like.

The thickness of the individual layers making up the AR stack 115 may vary widely. In general, the thickness of the layers within AR stack 115 should be tuned to work in conjunction with the adhesion layer 113, moth eye layer 111 and base substrate material or stack of materials. In general, however, the thickness of each layer within the AR stack 115 may have a thickness ranging from greater than 0 to about 250 nm or more, such as from greater than 0 to about 150 nm, from greater than 0 to about 100 nm, or even greater than 0 to about 90 nm. In any case, the makeup and thicknesses of the layers in AR stack 115 may be selected such that AR stack 115 provides a wide band antireflective effect in a wavelength range of about 400 to about 700 nm.

In embodiments the layers of the AR stack are configured such that a greater than or equal to a desired portion of a total thickness of the AR stack is made up of a particular type of layer. For example, in embodiments the AR stack includes a plurality of low index first layers, wherein a total thickness of the plurality of low index layers is greater than or equal to about 65%, about 70%, about 75%, about 80%, or even about 85% of the total thickness of the AR stack. Put differently, in such embodiments a total thickness of high index layers in the AR stack is less than or equal to about 35%, about 30%, about 25%, about 20%, or even about 15% of the total thickness of the AR stack.

In embodiments the thickness of the first layer in the AR stack and the thickness of the adhesion layer are selected such that a total thickness of the first layer in the AR stack and the adhesion layer are within a desire range. For example, in embodiments the first layer of the AR stack is formed directly on the adhesion layer, and the total thickness of the first layer of the AR stack and the adhesion layer ranges from about 90 to about 140 nm, such as from about 100 to about 130 nm. In some embodiments the total thickness of the first layer of the AR stack and the adhesion layer are within those ranges, and the first layer has a refractive index of about 1.44 to about 1.48. In such embodiments, the adhesion layer may also have a refractive index of about 1.44 to about 1.48. In specific non-limiting embodiments the AR stack 115 is formed directly on adhesion layer 113, and includes a low-index first layer having refractive index of between about 1.44 and about 1.48; a high-index second layer having refractive index of between 2.35-2.45 and thickness of between 20 and 26 nm; a low-index third layer having refractive index of between 1.44 and 1.48 and thickness of between 27 and 35 nm; a high-index fourth layer having refractive index of between 2.35-2.45 and thickness of between 27 and 35 nm; and a low-index fifth layer having refractive index of between 1.44 and 1.48 and thickness of between 85 and 105 nm; wherein a total thickness of the adhesion layer and the low-index first layer is between about 100 nanometers (nm) and about 130 nm.

The upper surface of the AR stack 115 may have a surface roughness that is different from the surface roughness of the as-deposited adhesion layer 113 and the as-formed moth eye layer 111. For example, the upper surface of the AR stack 115 may have a surface roughness (R3), the upper surface of the as-deposited adhesion layer 113 may have a surface roughness (R2), and the upper surface of the as-formed moth eye layer 111 may have a surface roughness (R1), wherein R3<R2<R1.

To demonstrate that concept a multilayer AR article 100 consistent with the structure of FIG. 8 was produced, in which an AR stack 115 including a plurality of alternating SiO₂ (119a) and TiO₂ (121b) were formed on an upper surface of an SiOₓ adhesion layer 113 formed on a moth eye layer 111. The thickness of the respective layers in that example AR stack 115 is provided in Table 1 below. All refractive index values discussed within the context of this application refer to refractive index measured at 550 nm. It is noted that the AR stack 115 forms a durable AR coating on adhesion layer 113 and moth eye layer 111. While AR stack 115 is optically designed to work with layers 111 and 113, it includes thick layers of SiO2 and relatively thinner layers of TiOx. As known in the art, amorphous TiO2 is softer in comparison to SiO2. On the Mohs Hardness Scale, SiO2 is rated between 6-7 while amorphous TiO2 is rated between 5-6. On the nanoindentation hardness scale, SiO2 is measured between 6.5-8 GPa while amorphous TiO2 is measured between 5.5-6.5 GPa. With that in mind, many known AR stacks include alternating SiO₂ (low index) and TiO₂ (high index) layers, wherein a total thickness of the SiO₂ layers is less than 60% of the total thickness of the AR stack. In contrast, embodiments of the present disclosure employ an AR stack including a plurality of alternating low and high index layers, wherein the total thickness of the low index layers is greater than 60% (e.g., greater than or equal to about 65%, 70%, 75%, or even 80%) of the total thickness of the AR stack. In embodiments, the total thickness of the low refractive index layers in the AR stacks described herein is greater than or equal to about 75% or even about 80% of the total thickness of the AR stack. In such embodiments, the low refractive index layers may be formed from SiO₂ or another suitable low refractive index material, and the high refractive index layers may be formed from TiO₂ or another suitable high refractive index material.

The AR stack composition as listed in Table 1 has an overall thickness of 260.1 nm. Of this overall thickness, the low index SiO2 layer thickness is 206.79 nm or 79.5% of the total. As documented in the example, this composition provides improved article scratch test performance.

TABLE 1
Layer thicknesses for an example AR stack

| | | Thickness |
|---|---|---|
| Layer | Index | (nm) |
| 119₃ (SiO₂) | 1.465 | 96.22 |
| 121₂ (TiO₂) | 2.386 | 30.31 |
| 119₂ (SiO₂) | 1.465 | 30.55 |
| 121₁ (TiO₂) | 2.386 | 23.00 |
| 119₁ (SiO₂) | 1.465 | 80.02 |
| 113 (Adhesion Layer) - SiOₓ | 1.47 | 37.12 |

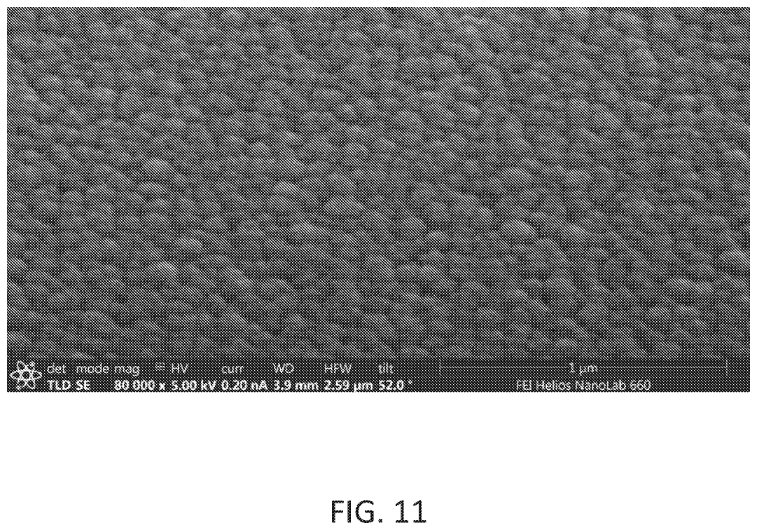

An SEM image of the upper surface 801 of the AR stack 115 was taken, and is shown in FIG. 11. As can be seen, the surface roughness of adhesion layer 113 was further smoothed following deposition of the AR stack 115.

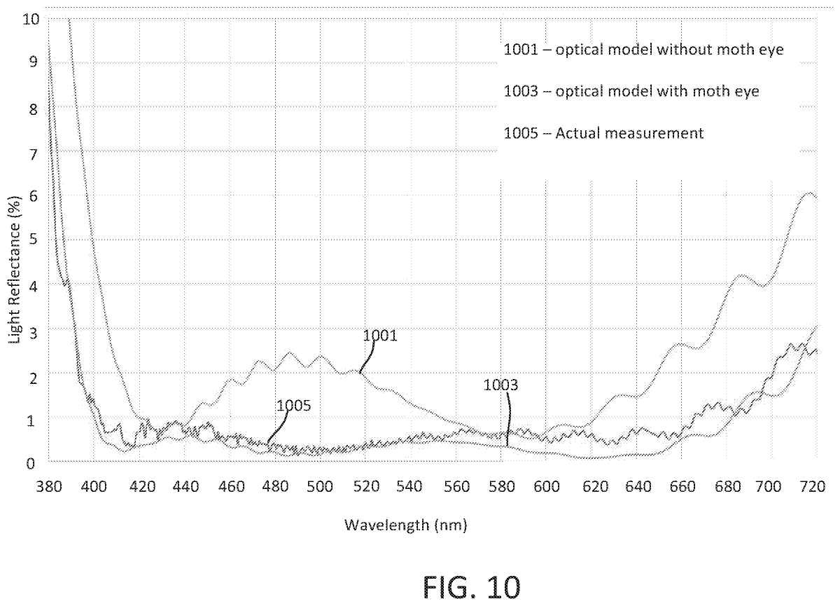

To further demonstrate the impact of the moth eye layer on optical design of a multilayer AR article, the multilayer AR article discussed above regarding FIG. 8, Table 1 and FIG. 11 was subjected to reflectance testing, and the results were compared to the results of an optical model 1001 in which the moth eye layer was not present, and the results of an optical model 1003 in which the moth eye layer was present as a discrete optical element in the design. The results of that comparison are shown in FIG. 10. As shown, there was a relatively close correlation between the actual measurement 1005 of the layer stack and the optical model 1003 that treated the moth eye layer as a discrete optical element. This is believed to be due to the fact that the thickness of tailored to work in conjunction with and take advantage of the anti-reflective effect of the moth eye layer 111. This technique is different from conventional anti-reflective optical design and is made possible by the non-conformal deposition of adhesion layer 113 preserving the moth-eye layer 111 anti-reflective effect. As also shown by optical model 1001 in FIG. 10, the AR stack 115 (without moth-eye layer 115) exhibited relatively poor anti-reflection performance, particularly in 450 nm-550 nm region in which reflection is approximately 3 times higher than that of combined stack 1005.

Turning now to FIG. 9A, an anti-smudge layer 117 may optionally be formed on an upper surface of AR stack 115. A wide variety of anti-smudge layers are known and any suitable anti-smudge layer may be used. In some embodiments, the anti-smudge layer 117 is an anti-fingerprint, anti-smudge fluoropolymer layer, such as those known in the art. Without limitation, in some embodiments, the anti-smudge layer 117 can include an interface layer 901, a primer layer 903 and an anti-fingerprint layer 905, as shown in FIG. 9B. Such layers may be applied in any suitable manner, such as by a wet coating process or a vacuum evaporation process. Without limitation, in some embodiments anti-smudge layer 117 is a fluoropolymer layer that is applied via a dip coating process. It is also understood that the AR stack 115 needs to be designed to work with top anti-smudge layer 117 to achieve desired final optical performance. To illustrate that concept, a layer stack consistent with the structure of FIG. 9A was formed in much the same manner as the examiner discussed above regarding FIG. 10 and table 1, except that an anti-smudge layer 117 having an index of 1.36 was formed on the upper surface of the AR stack 115. The thickness of the individual layers in the AR stack 115 and the anti-smudge layer 117 are reported in table 2 below.

TABLE 2
Layer thicknesses for an example AR
stack with an Anti-Smudge Layer

| | | Thickness |
|---|---|---|
| Layer | Index | (nm) |
| 117 | 1.36 | 20.00 |
| 119₃ (SiO₂) | 1.465 | 81.34 |
| 121₂ (TiO₂) | 2.386 | 30.31 |
| 119₂ (SiO₂) | 1.465 | 30.55 |
| 121₁ (TiO₂) | 2.386 | 23.00 |
| 119₁ (SiO₂) | 1.465 | 80.02 |
| 113 (Adhesion Layer) - SiOₓ | 1.47 | 37.12 |

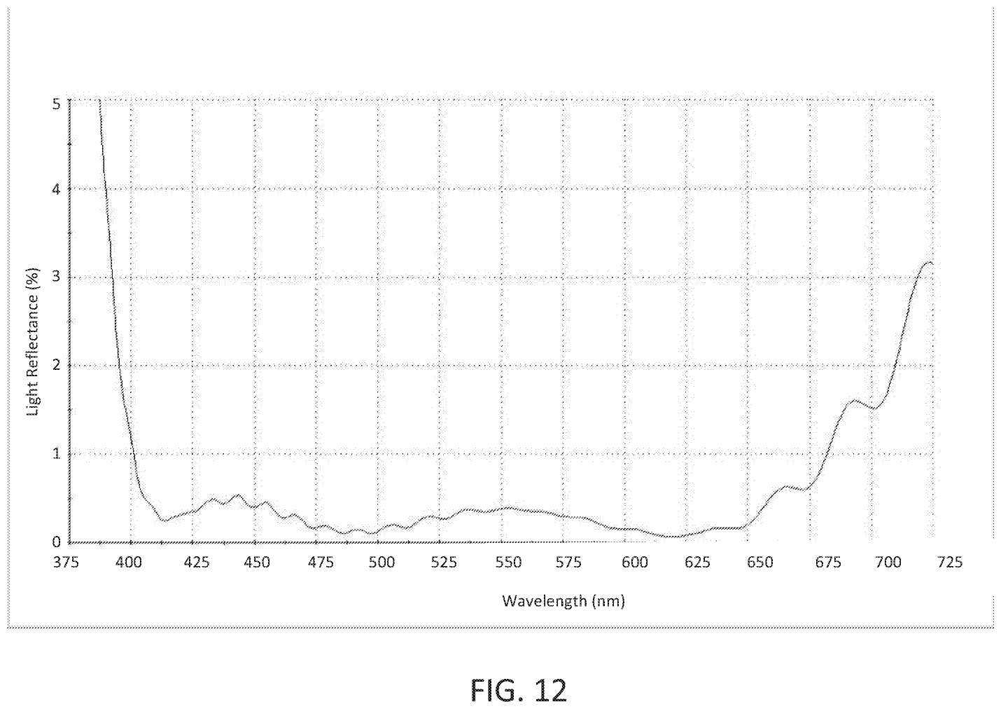

As can be seen, the thickness of the uppermost layer 1193 in the AR stack 115 was adjusted (relative to the thickness of the uppermost layer 1193 in table 1) to account for the impact of the anti-smudge layer. The optical performance of the resulting structure was measured, and the results are plotted in FIG. 12.

The present disclosure is further detailed with respect to the following example, which is intended to illustrate specific example embodiments.

### TEST EXAMPLES

In applications such as mobile phone screen overlays, strong adhesion of an AR coating to a base structure is an important design parameter. Indeed, if the AR coating does not sufficiently adhere to the base structure, its performance may deteriorate over time, and/or it may delaminate. This is particularly true in the context of smart phones and cell phones, where adhesion of an AR coating on a screen overlay may be severely tested when the device is used environments with elevated temperature and/or humidity, and when the device is subjected to normal wear and tear.

To investigate their usefulness for such applications, several sample multilayer AR articles consistent with the present disclosure were prepared. A hard-coated PET film sold by the Japanese corporation Nippa under part number T-CPF100(75)-SL(35) (hereinafter, the Nippa film) was used as a base structure 100 for each sample. The Nippa film included a polyethylene terephthalate substrate 103, which was hard coated with silicon and oxygen containing polymeric hard coating 109.

Eight (8) 76×158 mm pieces of the Nippa film were cut and laminated onto eight (8) 82.5×165 mm pieces of borosilicate glass having a thickness of 1.1 mm. All 8 pieces of the Nippa film were mounted in side by side vertical orientation on a 475×1000×12.5 mm aluminum carrier, such that they could be processed simultaneously.

The carrier was loaded into a single-ended vertical coating system that includes two process zones, one for ion source plasma etch, and another for AC ion source PE-CVD deposition. The carrier was initially placed in the plasma etch zone and subject to plasma etch to form a moth eye layer on the surface of hard coating of the Nippa film. The plasma etch was carried out by exposing the hard coating to a beam of oxygen ions that were produced by operating an ion source at 2.5 kilovolts, 400 mA using oxygen as the active gas. The incident angle of the ion beam was 45 degrees. Plasma etch was carried out as the carrier was moved past the ion source at a rate of 0.5 meters per minute.

The carrier was then moved to the PE-CVD zone and a SiOₓ adhesion layer was deposited on the moth eye layer. Deposition of the adhesion layer was performed by PE-CVD using HMDSO as the precursor vapor, which was delivered with oxygen gas to the plasma source as the carrier was moved past the source. The ratio between oxygen and precursor vapor was 5:1 (120 standard cubic centimeters per minute (sccm) HMDSO, 600 sccm Oxygen), and the AC ion source was operated at 5.6 kW as the carrier was moved at a rate of 4 m/min. The resulting SiOₓ adhesion layer had a refractive index of 1.45 and a thickness of 37.12 nm.

Following deposition of the adhesion layer, remaining layers of AR stack including a total of three SiO₂ layers and two TiO₂ layers were deposited on the upper surface of the adhesion layer. The first layer deposited on the adhesion layer was a SiO₂ layer having a refractive index of 1.476 and a thickness of 80.02 nm. Deposition was performed by PE-CVD using HMDSO as the precursor gas, which was delivered with oxygen to the plasma source as the carrier was moved past the course. The ratio of HMDSO to oxygen was 6.4:1 (55 sccm HMDSO, 350 sccm Oxygen), and the AC ion source was operated at 9.4 kW as the carrier was moved at 0.802 m/min.

A first layer of TiO₂ was then deposited on the first layer of SiO₂ having a refractive index of 2.386 and a thickness of 23.00 nm. The layer was formed via PE-CVD using TiCl₄ as the precursor vapor, which was delivered to the plasma source with oxygen gas as the carrier was moved past the source. The ratio between oxygen and precursor vapor was 7.8:1 (77 sccm TiCl4, 600 sccm Oxygen) and the AC ion source was operated at 10.8 kW while the carrier moved at a rate of 0.902 m/min.

Following layers of TiO₂ and SiO₂ were then deposited in much the same manner as the first TiO₂ and SiO₂ layers, using the following processing parameters: second SiO₂ layer (RI 1.465, physical thickness 30.55 nm, 9.4 kW, 55 sccm HMDSO, 350 sccm Oxygen, Carrier Speed 2.44 m/min); second TiO₂ layer (RI 2.386, physical thickness 30.31 nm, 10.8 kW, 77 sccm TiCl4, 600 sccm Oxygen, Carrier speed 0.631 m/min); and then third SiO₂ (RI 1.465, physical thickness 96.05 nm, 9.4 kW, 55 sccm HMDSO, 350 sccm Oxygen, Carrier Speed 0.621 m/min). The resulting multilayer AR articles had the general layer structure shown in FIG. 5D. Following the formation of the AR stack, a fluoropolymer anti-smudge coating was provided on some of the samples via vacuum evaporation. The resulting multilayer AR articles had the general structure of the multilayer AR article shown in FIG. 9A.

To evaluate their optical performance, one of the multilayer AR articles was applied to the display of a smart phone and the reflectance of the sample in the visible region of the electromagnetic spectrum was measured. The results are shown in FIG. 12. As shown, the sample exhibited a reflectance less than 1% of visible light over the wavelength range of about 400 to about 680 nm. To evaluate scratch resistance, prepared multilayer AR articles corresponding with FIG. 8 and Table 1 were subject to scratch testing (article without anti-smudge top coating). Testing was performed using an automated scratch tester with #0000 and #00 steel wool covering a 1 cm² “finger” and using a 1000 gram weight. Scratch resistant was evaluated by comparing change in haze (measured by Haze-Gard measurement) pre versus post scratching. Samples exhibited excellent scratch resistant performance. The haze only increased from 0.52% to 0.59% after 1000 passes of #0000 steel wool with 1 kg weight and only increased from 0.52% to 0.75% after 1000 passes of #00 steel wool with 1 kg weight.

To evaluate the adhesion strength of the AR stack and other layers, some of the multilayer AR articles prepared above were subject to a rigorous adhesion test. The adhesion test utilized a grid and tape method that, if passed, can help to ensure satisfactory performance of the multilayer AR article in real world applications, such as an overlay of mobile device display.

The adhesion test was performed in accordance with ASTM D3359-09, as described below. Following deposition of the AR stack 115, a 10×10 grid of 1 mm×1 mm squares was formed in the samples that were not coated with a fluoropolymer anti-smudge layer. The grid was cut through the AR stack, the adhesion layer, and into the moth eye layer using a diamond tip pen. Tape (3M® SCOTCH® Invisible Tape) was then pressed firmly down over the cut grid area and pulled off sharply. The grid area was then inspected for coating delamination, which may range from complete removal of grid squares to partial coating removal at the edges. No delamination was observed in the tested samples following the initial tape test.

The test samples were then placed in an environmental chamber set at 60 degrees Celsius and 90% humidity. After 72 hours, the tape test was reiterated using the same grid, and no delamination was observed. The samples were then returned to the environmental chamber and the test was reiterated every 72 hours for a total of thirty days. No delamination of any of the grid squares was observed for any of the samples over the entire period of the test.

To demonstrate the impact of the moth eye layer on the design of the AR stack, optics software was utilized to calculate a simulated reflectance of the sample structures produced above using convention AR design techniques. Specifically, optics software was used to calculate the simulated reflectance of the samples based on the use of the Nippa film, and the AR stack layer as discrete optical components in the layer structure, but without considering the moth eye layer as part of overall optical design. The simulated reflectance data produced for this structure is plotted as plot 1001 in FIG. 10. In addition, the simulated reflectance data that includes moth eye layer is plotted as plot 1003. The measured reflectance of the samples is plotted in the same figure as plot 1005. As can be seen, there is a significant discrepancy between the simulated data (1001) and the real-world data 1005. On the other hand, there is a close correlation between simulated data (1003) and the real-world data 1005. This demonstrates and confirms the need to take the moth eye layer into account when calculating the design of the AR stack.

As used herein, the terms “about” and “substantially” when used regarding a numerical value or range means +/−5% of the recited numerical value or range.

As used herein, the term “on” may be used to describe the relative position of one component (e.g., a first layer) relative to another component (e.g., a second layer). In such instances the term “on” should be understood to indicate that a first component is present above a second component, but is not necessarily in contact with one or more surfaces of the second component. That is, when a first component is “on” a second component, one or more intervening components may be present between the first and second components. In contrast, the term “directly on” should be interpreted to mean that a first component is in contact with a surface (e.g., an upper surface) or a second component. Therefore, when a first component is “directly on” a second component, it should be understood that the first component is in contact with the second component, and that no intervening components are present between the first and second components.

### ADDITIONAL EXAMPLES

The following examples are additional embodiments of the present disclosure.

### Example 1

According to this embodiment there is provided a multilayer antireflective article, including: a base structure comprising a substrate and a hard-coat layer on an upper surface of the substrate; a moth eye layer etched into said hard-coat layer; a non-conformal adhesion layer on said moth eye layer; and an anti-reflective (AR) stack including a plurality of layers of differing refractive index on said adhesion layer.

### Example 2

This example includes any or all of the features of example 1, wherein: said plurality of layers of differing refractive index include a plurality of first layers and plurality of second layers; the plurality of first layers have a relatively low refractive index, as compared to the plurality of second layers; the AR stack has a total thickness; and a total thickness of said plurality of first layers is greater than 75% of the total thickness of said AR stack.

### Example 3

This example includes any or all of the features of example 2, wherein the plurality of first layers consist of a first material having a refractive index ranging from about 1.44 to about 1.48.

### Example 4

This example includes any or all of the features of any one of examples 1 to 3, wherein: the adhesion layer has a refractive index between about 1.44 to about 1.48; the AR stack is formed directly on the adhesion layer, and said plurality of layers include, in succession: a low-index first layer having refractive index of between about 1.44 and about 1.48; a high-index second layer having refractive index of between 2.35-2.45 and thickness of between 20 and 26 nm; a low-index third layer having refractive index of between 1.44 and 1.48 and thickness of between 27 and 35 nm; a high-index fourth layer having refractive index of between 2.35-2.45 and thickness of between 27 and 35 nm; and a low-index fifth layer having refractive index of between 1.44 and 1.48 and thickness of between 85 and 105 nm; wherein a total thickness of the adhesion layer and the low-index first layer is between about 100 nanometers (nm) and about 130 nm.

### Example 5

This example includes any or all of the features of example 4, and further includes an anti-smudge layer on the low-index fifth layer, wherein the anti-smudge layer has a refractive index ranging from about 1.3 to about 1.4; and a total thickness of the low-index fifth layer and the anti-smudge layer is between about 85 nm and about 105 nm.

### Example 6

This example includes any or all of the features of any of examples 1 to 5, wherein the multilayer antireflective article exhibits a scratch resistance strength that can withstand at least 1000 passes of #0000 steel wool under 1 kg/cm² with less than 0.5% change in total haze.

### Example 7

This example includes any or all of the features of any of examples 1 to 6, wherein the multilayer antireflective article exhibits an adhesion strength that can withstand at least 30 days in environment of at least 50° C. and at least 90% humidity when subject to a grid and tape test.

### Example 8

This example includes any or all of the features of any of examples 1 to 7, wherein the substrate is a polymer.

### Example 9

This example includes any or all of the features of any of examples 1 to 8, wherein the substrate is an acrylate polymer or a terephthalate polymer.

### Example 10

This example includes any or all of the features of any of examples 1 to 9, wherein the hard coat layer is a sol gel hard coat layer.

### Example 11

This example includes any or all of the features of any of examples 1 to 9, wherein the hard coat layer is an alkoxide hard coat layer.

### Example 12

This example includes any or all of the features of example 2, wherein the plurality of first layers are formed from SiO₂, and the plurality of second layers are formed from TiO₂.

### Example 13

This example includes any or all of the features of any of examples 1 to 12, wherein the antireflective article reflects less than 1% of incident light in a wavelength range of about 400 to about 700 nanometers.

### Example 14

This example includes any or all of the features of example 4, wherein the low-index first layer, the low index third layer, and the low index fifth are each SiO₂, and the high-index second layer and high index fourth layer are each TiO₂.

### Example 15

A mobile device comprising an anti-reflective article in accordance with any one of examples 1 to 14.

As may be appreciated from the foregoing, the multilayer AR article described herein can include a highly adherent, broad band antireflective coating (e.g., layers 111, 113 and 115 and optionally 117) on a base structure 101 (e.g., a polymer substrate 103 including a hard coating 109). The multilayer AR articles can retain the benefits of a moth eye effect provided by a moth eye layer (e.g., layer 111) and an adhesion layer 113 and combines that effect with a multilayer AR stack that can withstand rigorous adhesion testing. As a result, the multilayer AR articles consistent with the present disclosure can be advantageously used in challenging applications, such as overlay screen protectors for mobile devices (smart phones, tablets, laptops, etc.) and automotive displays.

Other than in the examples, or where otherwise indicated, all numbers expressing endpoints of ranges, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present disclosure. At the very least, and not as an attempt to limit the application of the doctrine of equivalents to the scope of the claims, each numerical parameter should be construed in light of the number of significant digits and ordinary rounding approaches.

Notwithstanding that the numerical ranges and parameters setting forth the broad scope of the present disclosure are approximations, unless otherwise indicated the numerical values set forth in the specific examples are reported as precisely as possible. Any numerical value, however, inherently contains certain errors necessarily resulting from the standard deviation found in their respective testing measurements.

Other embodiments of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A multilayer antireflective article, comprising:
a base structure comprising a substrate and a hard-coat layer on an upper surface of the substrate;
a moth eye layer etched into said hard-coat layer;
a non-conformal adhesion layer on said moth eye layer; and
an anti-reflective (AR) stack comprising a plurality of layers of differing refractive indices on said adhesion layer.

2. The multilayer antireflective article of claim 1, wherein:
said plurality of layers of differing refractive index include a plurality of low refractive index layers and plurality of high refractive layers;
the plurality of low refractive index layers have a relatively low refractive index, as compared to the plurality of high refractive index layers;
the AR stack has a total thickness; and
a total thickness of said plurality of low refractive index layers is greater than 75% of the total thickness of said AR stack.

3. The multilayer antireflective article of claim 2, wherein the plurality of low refractive index layers consist of a first material having a refractive index ranging from about 1.44 to about 1.48.

4. The multilayer antireflective article of claim 1, wherein:
the adhesion layer has a refractive index between about 1.44 to about 1.48;
the AR stack is formed directly on the adhesion layer, and said plurality of layers include, in succession:
a low-index first layer having refractive index of between about 1.44 and about 1.48;
a high-index second layer having refractive index of between 2.35-2.45 and thickness of between 20 and 26 nm;
a low-index third layer having refractive index of between 1.44 and 1.48 and thickness of between 27 and 35 nm;
a high-index fourth layer having refractive index of between 2.35-2.45 and thickness of between 27 and 35 nm; and
a low-index fifth layer having refractive index of between 1.44 and 1.48 and thickness of between 85 and 105 nm;
wherein a total thickness of the adhesion layer and the low-index first layer is between about 100 nanometers (nm) and about 130 nm.

5. The multilayer antireflective article of claim 4, further comprising an anti-smudge layer on the low-index fifth layer, wherein:
the anti-smudge layer has refractive index between about 1.3 and about 1.4; and
a total thickness of the low-index fifth layer and the anti-smudge layer is between about 85 nm and about 105 nm.

6. The multilayer antireflective article of claim 1, wherein the multilayer antireflective article exhibits a scratch resistance strength that can withstand at least 1000 passes of #0000 steel wool under 1 kg/cm² with less than 0.5% change in total haze.

7. The multilayer antireflective article of claim 1, wherein the multilayer antireflective article exhibits an adhesion strength that can withstand at least 30 days in environment of at least 50° C. and at least 90% humidity without delamination when subject to a grid and tape test in accordance with ASTM D3359-09.

8. The multilayer antireflective article of claim 1, wherein the substrate is a polymer.

9. The multilayer antireflective article of claim 1, wherein the substrate is an acrylate polymer or a terephthalate polymer.

10. The multilayer antireflective article of claim 1, wherein the hard coat layer is a sol gel hard coat layer.

11. The multilayer antireflective article of claim 1, wherein the hard coat layer is an alkoxide hard coat layer.

12. The multilayer antireflective article of claim 2, wherein the plurality of flow refractive index layers are each formed from SiO₂, and the plurality of high refractive index layers are each formed from TiO₂.

13. The multilayer antireflective article of claim 1, wherein the antireflective article reflects less than 1% of incident light in a wavelength range of about 400 to about 700 nanometers.

14. The multilayer antireflective article of claim 4, wherein the low-index first layer, the low index third layer, and the low index fifth are each SiO₂, and the high-index second layer and high index fourth layer are each TiO₂.

15. A mobile device comprising a multilayer anti-reflective article, said multilayer antireflective article comprising:
a base structure comprising a substrate and a hard-coat layer on an upper surface of the substrate;
a moth eye layer etched into said hard-coat layer;
a non-conformal adhesion layer on said moth eye layer; and
an anti-reflective (AR) stack comprising a plurality of layers of differing refractive indices on said adhesion layer.

16. The mobile device of claim 15, wherein:
said plurality of layers of differing refractive index include a plurality of low refractive index layers and plurality of high refractive layers;
the plurality of low refractive index layers have a relatively low refractive index, as compared to the plurality of high refractive index layers;
the AR stack has a total thickness; and
a total thickness of said plurality of low refractive index layers is greater than 75% of the total thickness of said AR stack.

17. The mobile device of claim 15, wherein
the adhesion layer has a refractive index between about 1.44 to about 1.48;
the AR stack is formed directly on the adhesion layer, and said plurality of layers include, in succession:
a low-index first layer having refractive index of between about 1.44 and about 1.48;
a high-index second layer having refractive index of between 2.35-2.45 and thickness of between 20 and 26 nm;
a low-index third layer having refractive index of between 1.44 and 1.48 and thickness of between 27 and 35 nm;
a high-index fourth layer having refractive index of between 2.35-2.45 and thickness of between 27 and 35 nm; and
a low-index fifth layer having refractive index of between 1.44 and 1.48 and thickness of between 85 and 105 nm;
wherein a total thickness of the adhesion layer and the low-index first layer is between about 100 nanometers (nm) and about 130 nm.

18. The mobile device of claim 16, wherein
the adhesion layer has a refractive index between about 1.44 to about 1.48;
the AR stack is formed directly on the adhesion layer, and said plurality of layers include, in succession:
a low-index first layer having refractive index of between about 1.44 and about 1.48;
a high-index second layer having refractive index of between 2.35-2.45 and thickness of between 20 and 26 nm;
a low-index third layer having refractive index of between 1.44 and 1.48 and thickness of between 27 and 35 nm;
a high-index fourth layer having refractive index of between 2.35-2.45 and thickness of between 27 and 35 nm; and
a low-index fifth layer having refractive index of between 1.44 and 1.48 and thickness of between 85 and 105 nm;
wherein a total thickness of the adhesion layer and the low-index first layer is between about 100 nanometers (nm) and about 130 nm.

19. The mobile device of claim 15, wherein the multilayer antireflective article exhibits a scratch resistance strength that can withstand at least 1000 passes of #0000 steel wool under 1 kg/cm² with less than 0.5% change in total haze.

20. The mobile device of claim 15, wherein the multilayer antireflective article exhibits an adhesion strength that can withstand at least 30 days in environment of at least 50° C. and at least 90% humidity without delamination when subject to a grid and tape test in accordance with ASTM D3359-09.
